(19) United States
(12) Patent Application Publication
(10) Pub. No.: US 2024/0222548 A1
(43) Pub. Date: Jul. 4, 2024

(54) LIGHT EMITTING DIODE

(71) Applicant: Taiwan-Asia Semiconductor Corporation, Hsinchu City (TW)

(72) Inventors: Yi-Jen LIN, Hsinchu City (TW); Yen-Chun TSENG, Hsinchu City (TW); Tzu-Wen WANG, Hsinchu City (TW)

(21) Appl. No.: 18/500,180

(22) Filed: Nov. 2, 2023

(30) Foreign Application Priority Data
Dec. 29, 2022 (TW) 111150767

(51) Int. Cl. H01L 33/04; H01L 25/075; H01L 33/12; H01L 33/32

(52) U.S. Cl. CPC H01L 33/04; H01L 25/0753; H01L 33/12; H01L 33/32

(57) ABSTRACT

The present invention provides a light emitting diode, which includes a substrate, a first intermediary layer and a two-dimensional material structure. The first intermediary layer is located on the substrate. The two-dimensional material structure is located on the first intermediary layer, and the two-dimensional material structure is formed by stacking a plurality of two-dimensional material layers. The number of the plurality of two-dimensional material layers is not less than 2. The light with a specific wavelength is emitted or absorbed by the two-dimensional material structure.

### CROSS-REFERENCES TO RELATED APPLICATIONS

This application claims priority to Taiwan Patent Application No. 111150767 filed on Dec. 29, 2022, which is hereby incorporated by reference in its entirety.

### BACKGROUND OF THE INVENTION

### Field of the Invention

The present invention relates to a semiconductor optoelectronic device, in particular to a light emitting diode using a two-dimensional material structure.

### Descriptions of the Related Art

Recently, light emitting diodes have been widely used in lighting, medical and 3C products. At present, common light emitting diode chips are mainly made of various semiconductor materials. By the current flowing through the connection junction of two semiconductor materials, an electroluminescence effect is produced to convert electrical energy into light energy, enabling the light emitting diode chip to emit high-brightness light and be more energy-saving.

In the structure design of conventional light emitting diode chips, the problem of lattice mismatch often occurs due to the epitaxial stacking of different semiconductor materials. Especially at the connection junction of the different semiconductor materials mentioned above, it causes the characteristics and performance of the light emitting diode to be easily affected. In addition, although the conventional light emitting diode chips can change the emission wavelength by using different semiconductor materials, the conventional light emitting diode chips can only provide a single spectrum of emission wavelength, which has limitations in application.

Therefore, it is worthwhile to study how to design a light emitting diode that can solve the above problems.

### SUMMARY OF THE INVENTION

The objective of the present invention is to provide a light emitting diode using a two-dimensional material structure, which produces a light-emitting effect by stacking a plurality of two-dimensional material layers.

Another objective of the present invention is to provide a light emitting diode with multiple light-emitting wavelengths.

To achieve the above objectives, the light emitting diode of the present invention includes a substrate, a first intermediary layer and a two-dimensional material structure. The first intermediary layer is located on the substrate. The two-dimensional material structure is located on the first intermediary layer, and the two-dimensional material structure is formed by stacking a plurality of two-dimensional material layers. The number of the plurality of two-dimensional material layers is not less than 2. Light with a specific wavelength is emitted or absorbed by the two-dimensional material structure.

In an embodiment of the present invention, the light emitting diode further includes a second intermediary layer located on the two-dimensional material structure.

In an embodiment of the present invention, the light emitting diode further includes at least one combined structure located between the two-dimensional material structure and the second intermediary layer. Each combined structure includes an additional intermediary layer and an additional two-dimensional material structure. An additional two-dimensional material structure is formed on the additional intermediary layer. The additional two-dimensional material structure is formed by stacking a plurality of additional two-dimensional material layers. The number of the additional two-dimensional material layers is not less than the number of the two-dimensional material layers. The additional two-dimensional material structure emits or absorbs light with a specific wavelength or another additional specific wavelength.

In an embodiment of the present invention, when the at least one combined structure includes a plurality of combined structures, the number of the additional two-dimensional material layers of the additional two-dimensional material structure of any one target combined structure of the at least one combined structure is not greater than the number of the additional two-dimensional material layers of the additional two-dimensional material structure of an adjacent combined structure stacked on the target combined structure.

In an embodiment of the present invention, the number of the additional two-dimensional material layers is not more than 50.

In an embodiment of the present invention, the two-dimensional material layers and the additional two-dimensional material layers are composed of the same two-dimensional material.

In an embodiment of the present invention, the material of each of the two-dimensional material layers is selected from the group consisting of molybdenum disulfide (MoS₂), tungsten disulfide (WS₂), molybdenum diselenide (MoSe₂) and tungsten diselenide (WSe₂).

In an embodiment of the present invention, the first intermediary layer and the second intermediary layer are composed of indium gallium nitride or aluminum indium gallium nitride.

In an embodiment of the present invention, the substrate is made of gallium nitride material or sapphire material.

In an embodiment of the present invention, the light emitting diode further includes a buffer layer. The buffer layer is located between the substrate and the first intermediary layer, and the buffer layer is composed of a single layer of two-dimensional material.

In an embodiment of the present invention, the specific wavelength is between 670 nm and 1630 nm.

Accordingly, the light emitting diode of the present invention uses a two-dimensional material structure as the light-emitting layer, and the two-dimensional material structure can avoid the problem caused by the lattice mismatch with other semiconductor materials. In addition, by stacking a plurality of two-dimensional material structures, the light emitting diode of the present invention can simultaneously provide light of multiple light-emitting wavelengths or enhance the light-emitting intensity of specific light-emitting wavelengths, which can further expand its field of use and increase its application flexibility.

### BRIEF DESCRIPTION OF THE DRAWINGS

FIG. 1 is a schematic view of the first embodiment of the light emitting diode of the present invention.

FIG. 2 is a schematic view of a second embodiment of the light emitting diode of the present invention.

FIG. 3 is a schematic view of a third embodiment of the light emitting diode of the present invention.

FIG. 4 is a schematic view of the fourth embodiment of the light emitting diode of the present invention.

FIG. 5 is a schematic view of the fifth embodiment of the light emitting diode of the present invention.

FIG. 6 is a schematic view of the sixth embodiment of the light emitting diode of the present invention.

### DETAILED DESCRIPTION OF THE PREFERRED EMBODIMENT

Since the various aspects and embodiments are merely illustrative and not restrictive, after reading this specification, a person having ordinary skill in the art may also have other aspects and embodiments without departing from the scope of the present invention. The features and advantages of these embodiments and the scope of the patent application will be better appreciated from the following detailed description.

Herein, “a” or “an” is used to describe one or more devices and components described herein. Such a descriptive term is merely for the convenience of illustration and to provide a general sense of the scope of the present invention. Therefore, unless expressly stated otherwise, the term “a” or “an” is to be understood to include one or at least one, and the singular form also includes the plural form.

Herein, the terms “first” or “second” and similar ordinal numbers are mainly used to distinguish or refer to the same or similar devices or structures, and do not necessarily imply the spatial or temporal order of such devices or structures. It should be understood that in certain situations or configurations, ordinal numbers may be used interchangeably without affecting the practice of the present invention.

As used herein, the term “comprise” “include,” “have” or any other similar term is not intended to exclude additional, unrecited elements. For example, a device or structure comprising/including/having a plurality of elements is not limited to the elements listed herein but may comprise/include/have other elements not explicitly listed but generally inherent to the device or structure.

Please refer to FIG. 1, which is a schematic view of the first embodiment of the light emitting diode of the present invention. As shown in FIG. 1, the light emitting diode 1 of the present invention includes a substrate 10, a first intermediary layer 20 and a two-dimensional material structure 30. The substrate 10 is the basic structure of the light emitting diode 1. In the present invention, the substrate 10 may be made of gallium nitride (GaN) or sapphire, but the present invention is not limited thereto. The substrate 10 may also be made of other semiconductor materials.

The first intermediary layer 20 is located on the substrate 10. In the present invention, the first intermediary layer 20 is composed of indium gallium nitride (InGaN) or aluminum indium gallium nitride (AlInGaN), but the present invention is not limited thereto. The first intermediary layer 20 may also be composed of other materials. The first intermediary layer 20 is used as a connection layer between the substrate 10 and the two-dimensional material structure 30.

The two-dimensional material structure 30 is located on the first intermediary layer 20. The two-dimensional material structure 30 is stacked with a plurality of two-dimensional material layers 31, and each two-dimensional material layer 31 is composed of a single atomic layer of two-dimensional material. The two-dimensional material structure 30 is mainly used as a light-emitting layer. In the present invention, the two-dimensional material layers 31 of the two-dimensional material structure 30 may be composed of the same two-dimensional material, but the present invention is not limited thereto. The two-dimensional material layers 31 may also be composed of different two-dimensional materials for different two-dimensional material layers 31, e.g., transition metal chalcogenide. The material of each two-dimensional material layer 31 described herein is selected from the group consisting of molybdenum disulfide (MoS₂), tungsten disulfide (WS₂), molybdenum diselenide (MoSe₂) and tungsten diselenide (WSe₂).

In the design, the number of the two-dimensional material layers 31 of the two-dimensional material structure 30 is not less than two. Therefore, by stacking the two-dimensional material layers 31, the two-dimensional material structure 30 can provide the effect of emitting light of a specific wavelength. Furthermore, since different numbers of the two-dimensional material layers 31 have different energy gaps and can emit light of different wavelengths, the present invention can adjust the number of two-dimensional material layers 31 to change the specific wavelength of the emitted light. For example, when the number of the two-dimensional material layers 31 is two, the wavelength of the light emitted by the two-dimensional material structure 30 is approximately 670 nm. When the number of the two-dimensional material layers 31 is fifty, the wavelength of the light emitted by the two-dimensional material structure 30 is approximately 1630 nm. In other words, in an embodiment of the present invention, the specific wavelength of the light emitted by the two-dimensional material structure 30 is approximately between 670 nm and 1630 nm. Here, the number of the two-dimensional material layers 31 in the two-dimensional material structure 30 is not more than fifty, but the present invention is not limited thereto.

In an embodiment of the present invention, the light emitting diode 1 of the present invention may further include a second intermediary layer 40 (shown as a dotted line in FIG. 1). The second intermediary layer 40 is located on the two-dimensional material structure 30. By arranging the second intermediary layer 40, the light emitting diode 1 of the present invention can indirectly add other electrical devices or structures to the two-dimensional material structure 30 according to different design requirements.

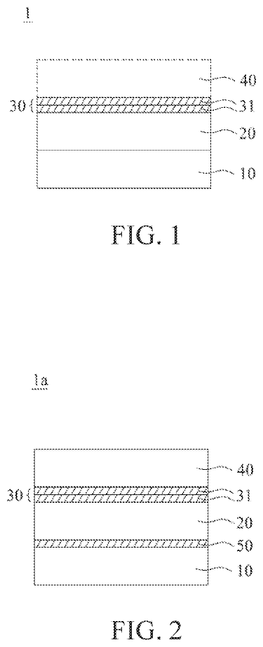

Please refer to FIG. 2, which is a schematic view of a second embodiment of the light emitting diode of the present invention. As shown in FIG. 2, in this embodiment, the light emitting diode 1a of the present invention further includes a buffer layer 50. The buffer layer 50 is located between the substrate 10 and the first intermediary layer 20, and the buffer layer 50 is used to mitigate the stress on the surface of the substrate 10 to provide a better interface bonding effect between the substrate 10 and the first intermediary layer 20. In the present invention, the buffer layer 50 can be composed of a single layer of two-dimensional material, and the two-dimensional material herein may also be selected from the group consisting of molybdenum disulfide (MoS₂), tungsten disulfide (WS₂), molybdenum diselenide (MoSe₂) and tungsten diselenide (WSe₂), e.g., it can use the same two-dimensional material as the aforementioned two-dimensional material layers 31, but the present invention is not limited thereto.

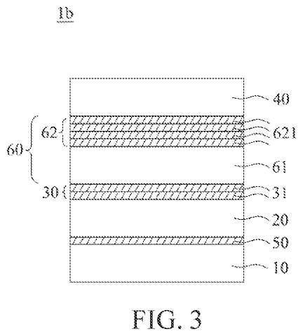

Please refer to FIG. 3, which is a schematic view of a third embodiment of the light emitting diode of the present invention. This embodiment is a variation of the aforementioned first embodiment, in which the design of the combined structure is mainly added. As shown in FIG. 3, in this embodiment, the light emitting diode 1b of the present invention further includes at least one combined structure 60. The at least one combined structure 60 is located between the two-dimensional material structure 30 and the second intermediary layer 40. Here, a single combined structure 60 is taken as an example for explanation, but the number of at least one combined structure 60 may include a plurality of combined structures. The combined structure 60 includes an additional intermediary layer 61 and an additional two-dimensional material structure 62, and the additional two-dimensional material structure 62 is formed on the additional intermediary layer 61. Therefore, when the combined structure 60 is located on the two-dimensional material structure 30, the additional two-dimensional material structure 62 can be separated from the two-dimensional material structure 30 by the additional intermediary layer 61 to avoid mutual interference. In the present invention, the additional intermediary layer 61 of the combined structure 60 is also made of indium gallium nitride or aluminum indium gallium nitride, but the present invention is not limited thereto.

The additional two-dimensional material structure 62 is stacked with a plurality of additional two-dimensional material layers 621, and each additional two-dimensional material layer 621 is composed of a single atomic layer of two-dimensional material. The additional two-dimensional material structure 62 is also used as a light-emitting layer. In the present invention, the additional two-dimensional material layers 621 of the additional two-dimensional material structure 62 may be composed of the same two-dimensional material, but the present invention is not limited thereto. The additional two-dimensional material layers 621 may also be composed of different two-dimensional materials for different additional two-dimensional material layers 621. The material of each additional two-dimensional material layer 621 described herein is selected from the group consisting of molybdenum disulfide (MoS₂), tungsten disulfide (WS₂), molybdenum diselenide (MoSe₂) and tungsten diselenide (WSe₂).

In the structure design, the number of additional two-dimensional material layers 621 of the additional two-dimensional material structure 62 is not less than the number of two-dimensional material layers 31 of the two-dimensional material structure 30. In other words, the number of the additional two-dimensional material layers 621 of the additional two-dimensional material structure 62 is not less than two, either, and the number of the additional two-dimensional material layers 621 can only be greater than or equal to the number of the two-dimensional material layers 31. For example, in this embodiment, the number of the additional two-dimensional material layers 621 is four, and the number of the two-dimensional material layers 31 is two. Therefore, by stacking the additional two-dimensional material layers 621, the additional two-dimensional material structure 62 can emit light with an additional specific wavelength (i.e., the wavelength corresponding to the stack of four layers of the additional two-dimensional material layers 621), and the additional specific wavelength will be greater than the specific wavelength of the light emitted by the aforementioned two-dimensional material structure 30 (i.e., the wavelength corresponding to the stack of two layers of the two-dimensional material layers 31). Accordingly, the light emitting diode 1b of the present invention can simultaneously emit light with the specific wavelength and the additional specific wavelength. That is to say, the light emitting diode 1b of the present invention can simultaneously emit light of different wavelengths. In addition, the present invention can also adjust the number of additional two-dimensional material layers 621 to change the additional specific wavelength of the emitted light. For example, in the present invention, the additional specific wavelength of the light emitted by the additional two-dimensional material structure 62 is approximately between 670 nm and 1630 nm.

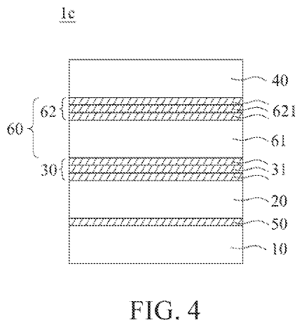

Please refer to FIG. 4, which is a schematic view of a fourth embodiment of the light emitting diode of the present invention. This embodiment is a variation of the aforementioned third embodiment, in which the design of the combined structure is mainly changed. As shown in FIG. 4, in this embodiment, the number of additional two-dimensional material layers 621 of the light emitting diode 1c of the present invention is three, and the number of the two-dimensional material layers 31 is also three. Therefore, with the premise that the two-dimensional material layers 31 and the additional two-dimensional material layers 621 all use the same material, the additional two-dimensional material structure 62 can emit light with the additional specific wavelength by stacking the additional two-dimensional material layers 621 (i.e., the wavelength corresponding to the stack of three layers of additional two-dimensional material layers 621), and the additional specific wavelength will be equal to the specific wavelength of the light emitted by the aforementioned two-dimensional material structure 30 (i.e., the wavelength corresponding to the stack of three layers of two-dimensional material layers 31). Accordingly, the light emitting diode 1b of the present invention can simultaneously emit light with an enhancement effect for the specific wavelength. In other words, the light emitting diode 1b of the present invention can provide the effect of enhancing the light of a single specific wavelength.

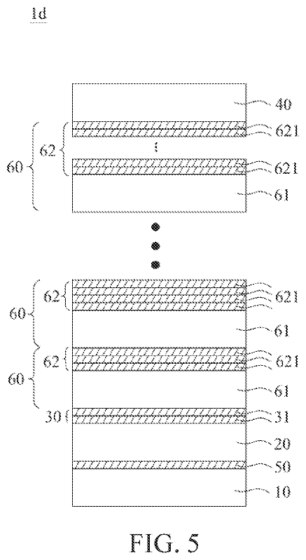

Please refer to FIG. 5, which is a schematic view of a fifth embodiment of the light emitting diode of the present invention. This embodiment is a variation of the aforementioned first embodiment, in which the design of a plurality of combined structures is mainly added. As shown in FIG. 5, in this embodiment, the light emitting diode 1d of the present invention further includes a plurality of combined structures 60. The combined structures 60 are located between the two-dimensional material structure 30 and the second intermediary layer 40, and the combined structures 60 are stacked one by one on the two-dimensional material structure 30. Each combined structure 60 includes an additional intermediary layer 61 and an additional two-dimensional material structure 62, and the additional two-dimensional material structure 62 is formed on the additional intermediary layer 61. Therefore, when any combined structure 60 is located on the two-dimensional material structure 30 or any two combined structures 60 are stacked with one another, the additional two-dimensional material structure 62 can be spaced apart from the two-dimensional material structure 30 or the additional two-dimensional material structure 62 by the additional intermediary layer 61 to avoid mutual interference.

Each additional two-dimensional material structure 62 is stacked with a plurality of additional two-dimensional material layers 621, and each additional two-dimensional material layer 621 is composed of a single atomic layer of two-dimensional material. Each additional two-dimensional material structure 62 is also used as a light-emitting layer. In the present invention, the additional two-dimensional material layers 621 of each additional two-dimensional material structure 62 may be composed of the same two-dimensional material, but the present invention is not limited thereto. Each plurality of additional two-dimensional material layers 621 can also be composed of different two-dimensional materials for different additional two-dimensional material layers 621. The material of each additional two-dimensional material layer 621 described herein is selected from the group consisting of molybdenum disulfide (MoS₂), tungsten disulfide (WS₂), molybdenum diselenide (MoSe₂) and tungsten diselenide (WSe₂).

In the structure design, the number of additional two-dimensional material layers 621 of each additional two-dimensional material structure 62 is not less than the number of two-dimensional material layers 31 of the two-dimensional material structure 30. In other words, the number of the additional two-dimensional material layers 621 of each additional two-dimensional material structure 62 is not less than two, either, and the number of the additional two-dimensional material layers 621 can only be greater than or equal to the number of the two-dimensional material layers 31. Furthermore, in a plurality of combined structures 60, the number of the additional two-dimensional material layers 621 of the additional two-dimensional material structure 62 of any target combined structure 60 is not greater than the number of the additional two-dimensional material layers 621 of the additional two-dimensional material structure 62 of another adjacent combined structure 60 stacked on the target combined structure 60. In other words, the number of the additional two-dimensional material layers 621 of the additional two-dimensional material structure 62 of each combined structure 60 can only be greater than or equal to the number of the additional two-dimensional material layers 621 of the additional two-dimensional material structure 62 of any underlying combined structure 60.

For example, in this embodiment, the combined structures 60 are stacked one by one on the two-dimensional material structure 30. The number of the two-dimensional material layers 31 of the two-dimensional material structure 30 is two. The number of the additional two-dimensional material layers 621 of the additional two-dimensional material structure 62 of the combined structure 60 closest to the two-dimensional material structure 30 is three. The number of the additional two-dimensional material layers 621 of the additional two-dimensional material structure 62 of the combined structure 60 second-closest to the two-dimensional material structure 30 is four. By analogy, the number of the additional two-dimensional material layers 621 of the additional two-dimensional material structure 62 of the combined structure 60 closest to the second intermediary layer 40 is n. Here, n is not greater than fifty; preferably, n is not greater than twenty, but the present invention is not limited thereto. Accordingly, since the numbers of the additional two-dimensional material layers 621 of the additional two-dimensional material structures 62 of the combined structures 60 are different from one another and increase upward, the light emitting diode 1d of the present invention can emit light with a specific wavelength range (e.g., including the light of the wavelength corresponding to the stack of two layers of the two-dimensional material layers 31 and the light of the wavelengths corresponding to the stacks of three to n layers of the additional two-dimensional material layers 621), thereby facilitating the light emitting diode 1d of the present invention to become a light emitting diode with a wide energy band.

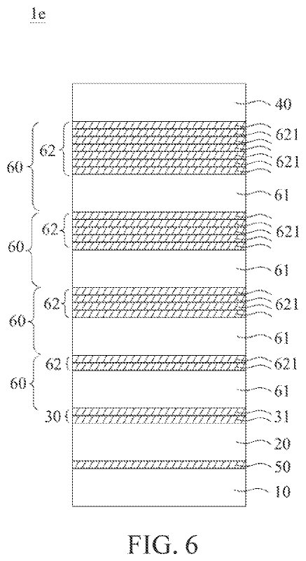

Please refer to FIG. 6, which is a schematic view of the sixth embodiment of the light emitting diode of the present invention. This embodiment is a variation of the aforementioned fifth embodiment, in which the design of the combined structures is mainly changed. As shown in FIG. 6, in this embodiment, the number of the two-dimensional material layers 31 of the two-dimensional material structure 30 of the light emitting diode 1e of the present invention is two. The number of the additional two-dimensional material layers 621 of the additional two-dimensional material structure 62 of the combined structure 60 closest to the two-dimensional material structure 30 is two. The number of the additional two-dimensional material layers 621 of the additional two-dimensional material structure 62 of the combined structure 60 second-closest to the two-dimensional material structure 30 is four. The number of the additional two-dimensional material layers 621 of the additional two-dimensional material structure 62 of the combined structure 60 third-closest to the two-dimensional material structure 30 is five. The number of the additional two-dimensional material layers 621 of the additional two-dimensional material structure 62 of the combined structure 60 closest to the second intermediary layer 40 is seven. Accordingly, the light emitting diode 1e of the present invention can emit the enhanced light of a single specific wavelength (e.g., the wavelength corresponding to the stack of two layers of the two-dimensional material layers 31 and two layers of the additional two-dimensional material layers 621), and can emit light with different additional specific wavelengths (i.e., the wavelengths corresponding to the stacks of four, five and seven layers of the additional two-dimensional material layers 621) at the same time, resulting in that the light emitting diode 1e of the invention is capable of flexibly providing different light-emitting wavelengths to expand its application.

The foregoing detailed description is illustrative in nature only and is not intended to limit the embodiments of the claimed subject matters or the applications or uses of such embodiments. Furthermore, while at least one exemplary embodiment has been presented in the foregoing detailed description, it should be appreciated that a wide variety of modifications to the present invention are possible. It should also be appreciated that the embodiments described herein are not intended to limit the scope, use, or configuration of the claimed subject matters in any way. Instead, the foregoing detailed description is intended to provide a person having ordinary skill in the art with a convenient guide for implementing one or more of the described embodiments. Moreover, various modifications may be made in the function and arrangement of the devices without departing from the scope defined by the claims, including known equivalents and any equivalents that may be anticipated at the time of filing this patent application.

What is claimed is:

1. A light emitting diode, comprising:
a substrate;
a first intermediary layer located on the substrate; and
a two-dimensional material structure located on the first intermediary layer, the two-dimensional material structure being formed by stacking a plurality of two-dimensional material layers, and a number of the two-dimensional material layers being not less than 2;
wherein light with a specific wavelength is emitted by the two-dimensional material structure.

2. The light emitting diode of claim 1, further comprising a second intermediary layer located on the two-dimensional material structure.

3. The light emitting diode of claim 2, further comprising at least one combined structure located between the two-dimensional material structure and the second intermediary layer, each of the at least one combined structures comprising:
an additional intermediary layer; and
an additional two-dimensional material structure formed on the additional intermediary layer, the additional two-dimensional material structure being formed by stacking a plurality of additional two-dimensional material layers, and a number of the additional two-dimensional material layers being not less than the number of the two-dimensional material layers;
wherein the additional two-dimensional material structure emits light with an additional specific wavelength, and the additional specific wavelength is not less than the specific wavelength.

4. The light emitting diode of claim 3, wherein when the at least one combined structure comprises a plurality of combined structures, the number of the additional two-dimensional material layers of the additional two-dimensional material structure of any one target combined structure of the at least one combined structure is not greater than the number of the additional two-dimensional material layers of the additional two-dimensional material structure of an adjacent combined structure stacked on the target combined structure.

5. The light emitting diode of claim 3, wherein the number of the additional two-dimensional material layers is not more than 50.

6. The light emitting diode of claim 3, wherein the two-dimensional material layers and the additional two-dimensional material layers are composed of a same two-dimensional material.

7. The light emitting diode of claim 6, wherein a material of each of the two-dimensional material layers is selected from the group consisting of molybdenum disulfide, tungsten disulfide, molybdenum diselenide and tungsten diselenide.

8. The light emitting diode of claim 2, wherein the first intermediary layer and the second intermediary layer are composed of indium gallium nitride or aluminum indium gallium nitride.

9. The light emitting diode of claim 1, wherein the substrate is made of gallium nitride material or sapphire material.

10. The light emitting diode of claim 1, further comprising a buffer layer located between the substrate and the first intermediary layer, the buffer layer being composed of a single layer of two-dimensional material.

11. The light emitting diode of claim 1, wherein the specific wavelength is between 670 nm and 1630 nm.
